(19) United States
(12) Patent Application Publication
(10) Pub. No.: US 2012/0279544 A1
(43) Pub. Date: Nov. 8, 2012

(54) THERMOELECTRIC MODULE

(75) Inventors: Dong Hyeok CHOI, Gyeonggi-do (KR); Yong Suk Kim, Gyeonggi-do (KR); Sung Ho Lee, Gyeonggi-do (KR)

(73) Assignee: SAMSUNG ELECTRO-MECHANICS CO., LTD.

(21) Appl. No.: 13/412,126

(22) Filed: Mar. 5, 2012

(30) Foreign Application Priority Data
May 2, 2011 (KR) 10-2011-0041400

(51) Int. Cl. H01L 35/32

(52) U.S. Cl. 136/224

(57) ABSTRACT

Disclosed herein is a thermoelectric module using a thermoelectric element capable of showing a spin Seebeck effect. The present invention provides a new thermoelectric module including: an upper substrate on which a plurality of upper metal electrodes are arranged; a lower substrate on which a plurality of lower metal electrodes are arranged; p-type semiconductor devices and n-type semiconductor devices that are disposed between the upper substrate and the lower substrate and are electrically bonded alternately to each other by the plurality of upper metal electrodes and the plurality of lower metal electrodes; and ferrite elements that are disposed between the p-type semiconductor devices and the n-type semiconductor devices, top ends and bottom ends of the ferrite elements being bonded to the upper metal electrodes and the lower metal electrodes.

### CROSS REFERENCE(S) TO RELATED APPLICATIONS

This application claims the benefit under 35 U.S.C. Section 119 of Korean Patent Application Serial No. 10-2011-0041400, entitled “Thermoelectric Module” filed on May 2, 2011, which is hereby incorporated by reference in its entirety into this application.

### BACKGROUND OF THE INVENTION

1. Technical Field

The present invention relates to a thermoelectric module, and more particularly, to a thermoelectric module using a spin Seebeck effect.

2. Description of the Related Art

A thermoelectric module is largely used for two applications, that is, power generation using a Seebeck effect and cooling using a Peltier effect.

The Seebeck effect is a phenomenon that generates electromotive force when a difference in temperature is generated at both ends of a thermoelectric element. The Seebeck effect is used for waste heat generation, a power supply for small electronic devices (for example, a watch) using body temperature, a power supply for a space probe using radioactive half reduction heat, or the like.

On the other hand, when current flows to both ends of the thermoelectric element, heat moves with the movement of charges. The phenomenon in which one end of the thermoelectric element is cooled and the other end of the thermoelectric element is heated is the Peltier effect. A cooling device using only electrons without a mechanical operation may be manufactured by using the Peltier effect.

FIG. 1 is a perspective view showing an inside of a thermoelectric module 100 according to the related art, FIG. 2 is a diagram showing a structure of p-type and n-type semiconductor devices and metal electrodes that are included in the thermoelectric module 100 according to the related art. The thermoelectric module 100 according to the related art is configured to largely include an insulating substrate 1, metal electrodes 2, p-type semiconductor devices 3, and n-type semiconductor devices 4 and has a series type single module form in which the p-type semiconductor devices through which holes move and the n-type semiconductor devices through which electrons move are electrically connected to each other in series through the metal electrodes.

The operation state in which the thermoelectric module 100 having the above configuration according to the related art is implemented will be described with reference to FIGS. 1 and 2. When the n-type thermoelectric semiconductor devices 4 and the p-type thermoelectric semiconductor devices 3 are electrically connected to each other in series via the metal electrodes 2 and apply DC current (D.C) via lead wires 5, heat absorption is generated at metal/semiconductor contacts 6 and 7 charged with negative by moving electrons absorbing heat energy from surroundings into a thermoelectric semiconductor and heat radiation is generated at the metal/semiconductor contacts 8 and 9 charged with positive by discharging heat energy from electrons.

However, even though the thermoelectric module is optimized by using a thermoelectric material, the heat absorption and/or heat radiation amount per supply power of a thermocouple, in which the n-type thermoelectric semiconductor and the p-type thermoelectric semiconductor are configured as a pair, is very insignificant. For this reason, when the thermoelectric module 100 according to the related art is actually used for a cooling device, or the like, the heat absorption and/or heat radiation amount is quantitatively increased by connecting a plurality of thermocouples and thus, the efficiency thereof is degraded in comparison to the manufacturing cost.

Further, as shown in FIG. 2, in the thermoelectric module 100 according to the related art, the p-type semiconductor devices and the n-type semiconductor devices are disposed to be spaced apart from each other at a predetermined interval so as to prevent a short between the p-type semiconductor devices and the n-type semiconductor devices. The module configuration having the form such as the thermoelectric module 100 according to the related art is easily damaged even by a small impact from the outside, such that the p-type semiconductor devices and the n-type semiconductor devices may be short.

In addition, since the thermoelectric module 100 is configured in a series type single module form in which the n and p-type semiconductor devices formed in plural pairs are electrically connected to each other in series via the metal electrodes, there is a fatal problem in that the overall composite module may not be operated if any one of the single modules is defective.

### SUMMARY OF THE INVENTION

An object of the present invention is to provide a thermoelectric module configured to include an upper substrate on which a plurality of upper metal electrodes are arranged, a lower substrate on which a plurality of lower metal electrodes are arranged, p-type semiconductor devices and n-type semiconductor devices that are disposed between the upper substrate and the lower substrate and are electrically bonded alternately to each other by the plurality of upper metal electrodes and the plurality of lower metal electrodes, and ferrite elements that are disposed between the p-type semiconductor devices and the n-type semiconductor devices.

According to an exemplary embodiment of the present invention, there is provided a thermoelectric module, including: an upper substrate on which a plurality of upper metal electrodes are arranged; a lower substrate on which a plurality of lower metal electrodes are arranged; p-type semiconductor devices and n-type semiconductor devices that are disposed between the upper substrate and the lower substrate and are electrically bonded alternately to each other by the plurality of upper metal electrodes and the plurality of lower metal electrodes; and ferrite elements that are disposed between the p-type semiconductor devices and the n-type semiconductor devices, top ends and bottom ends of the ferrite elements being bonded to the upper metal electrodes and the lower metal electrodes.

The ferrite element may include at least any one of spinel ferrite, garnet ferrite, and metal oxide.

One side of the ferrite element may be bonded to a p-type (or n-type) semiconductor device and/or the other side of the ferrite element may be bonded to an n-type (or p-type) semiconductor device.

The upper metal electrode and the lower metal electrode may be formed to have an n area in which the n-type semiconductor device is bonded thereto, a p area in which the p-type semiconductor device is bonded thereto, and f′, f″, and f′″ areas in which the ferrite element is bonded thereto.

A cross-sectional area of the f′ area may be formed to be wider than that of an n area or a p area, respectively.

### BRIEF DESCRIPTION OF THE DRAWINGS

FIG. 1 is a perspective view showing an inside of a thermoelectric module 100 according to the related art;

FIG. 2 is a structure diagram of p-type and n-type semiconductor devices and metal electrodes that are included in the thermoelectric module 100 according to the related art;

FIG. 3 is a perspective view showing the inside of the thermoelectric module according to the exemplary embodiment of the present invention;

FIG. 4 is a structure diagram showing the p-type and n-type semiconductor devices, ferrite elements, and the metal electrodes that are included in the thermoelectric module according to the exemplary embodiment of the present invention;

FIG. 5 is a diagram showing only a portion of an upper metal electrode included in the thermoelectric module according to the exemplary embodiment of the present invention; and

FIG. 6 is a diagram showing only a portion of a lower metal electrode included in the thermoelectric module according to the exemplary embodiment of the present invention.

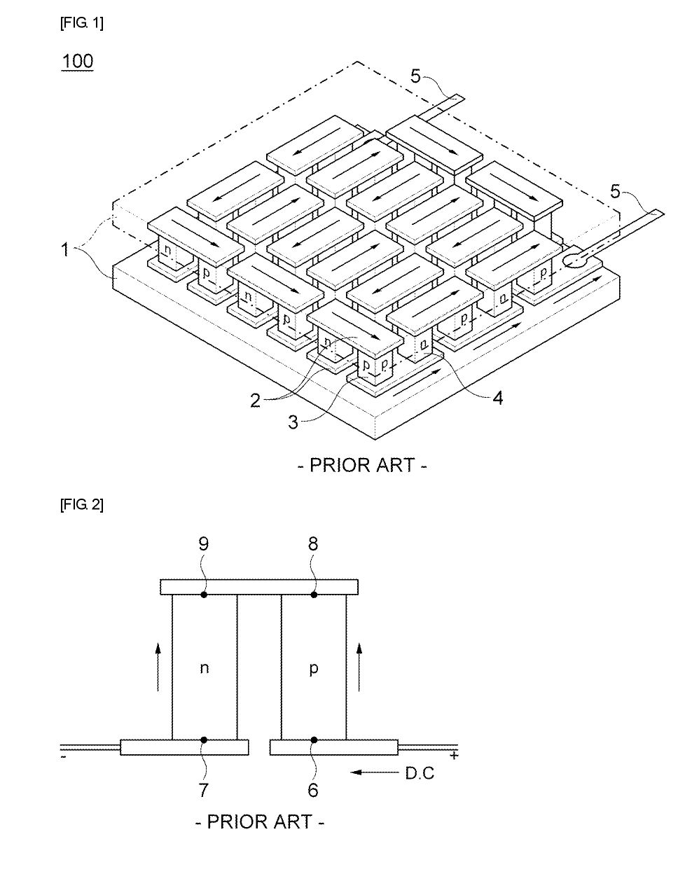

### DESCRIPTION OF THE PREFERRED EMBODIMENTS

Hereinafter, exemplary embodiments of the present invention will be described in detail with reference to the accompanying drawings. However, the exemplary embodiments of the present invention may be modified in various forms and the scope of the present invention is not limited to the exemplary embodiments described below. Exemplary embodiments of the present invention are provided so that those skilled in the art may more completely understand the present invention. Accordingly, shapes and sizes of elements in the drawings may be exaggerated for clear description and like reference numerals refer to like elements throughout the drawings.

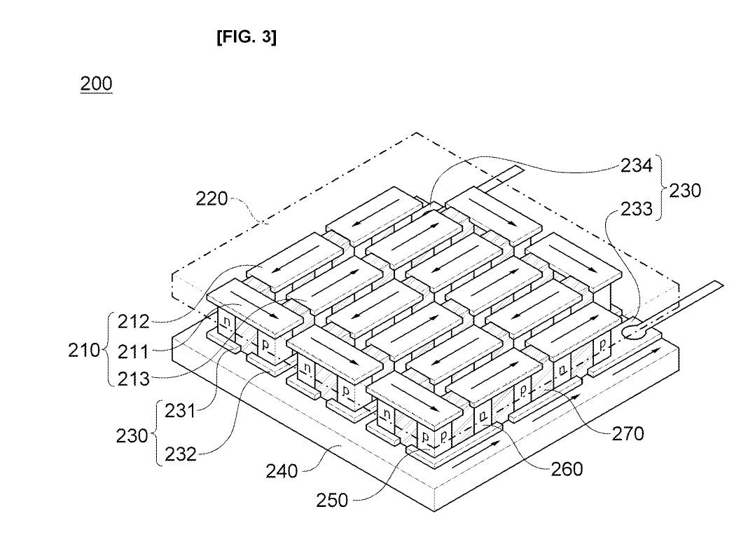

FIG. 3 is a perspective view showing an inside of a thermoelectric module 200 according to an exemplary embodiment of the present invention and FIG. 4 is a structure diagram showing p-type and n-type semiconductor devices 260, ferrite elements 270, and metal electrodes that are included in the thermoelectric module 200 according to the exemplary embodiment of the present invention.

Referring to FIGS. 3 and 4, the thermoelectric module 200 according to the exemplary embodiment of the present invention may be configured to include an upper substrate 220 on which a plurality of upper metal electrodes 210 are arranged, a lower substrate 240 on which a plurality of lower metal electrodes 230 are arranged, p-type semiconductor devices 250 and n-type semiconductor devices 260 that are disposed between the upper substrate 220 and the lower substrate 240 and are electrically bonded alternately to each other by the plurality of upper metal electrodes 210 and the plurality of lower metal electrodes 230, and ferrite elements 270 that are disposed between the p-type semiconductor devices 250 and the n-type semiconductor devices 260.

In this configuration, the ferrite element 270 may be made of a thermoelectric material showing a spin Seebeck effect. The thermoelectric material showing the spin Seebeck effect is a material that may indicate an effect of generating spin voltage only in a spin direction of electrons without moving electrons or holes by different spin polarities by moving electrons having an upward spin to a hot area and moving electrons having a down spin to a cold area when a magnetized metal is heated. In detail, the thermoelectric material is a soft ferrite material, not a general n-type and p-type thermoelectric material used in an existing thermoelectric module having semiconductor characteristics. The soft ferrite is an insulator without electrically moving electrons and means a magnetic material that may easily change the spin arrangement by an external magnetic field while having magnetic characteristics generated due to an arrangement of an electron spin. An example of a representative soft ferrite may include all the magnetic materials having soft magnetism among spinel ferrite having a chemical formula of MeOFe₂O₃ (where, Me may include Mn, Fe, Co, Ni, Cu, Zn, Mg, and Cd), garnet ferrite having a chemical formula of Re₃Fe₅O₁₂ (where, Re may include all the rare earth-based elements, and metal oxide.

Therefore, the ferrite element 270 may include at least any one of the spinel ferrite, the garnet ferrite, and the metal oxide.

One side of the ferrite element 270 may be bonded to the p-type (or n-type) semiconductor device and the other side of the ferrite element 270 may be bonded to the n-type (or p-type) semiconductor device. Alternatively, one side of the ferrite element 270 may be bonded to the p-type (or n-type) semiconductor device and the other side of the ferrite element 270 may be bonded to the n-type (or p-type) semiconductor device.

As described above, the ferrite element 270 used for the thermoelectric module according to the exemplary embodiment of the present invention is a ceramic magnetic substance using iron oxide (Fe₂O₃) including at least any one of the spinel ferrite, the garnet ferrite, and the metal oxide as a main component and thus, does not have conductivity. As a result, even though one side or both sides of the ferrite element 270 are bonded to the p-type or n-type semiconductor device 260, the ferrite element 270 does not affect the movement of heat by the p-type and n-type semiconductor devices to be described below and when one side or both sides of the ferrite element 270 are bonded to the p-type or n-type semiconductor devices 260, may maintain the shape of the p-type or n-type semiconductor devices 260 even from external force, thereby improving the durability of the thermoelectric module.

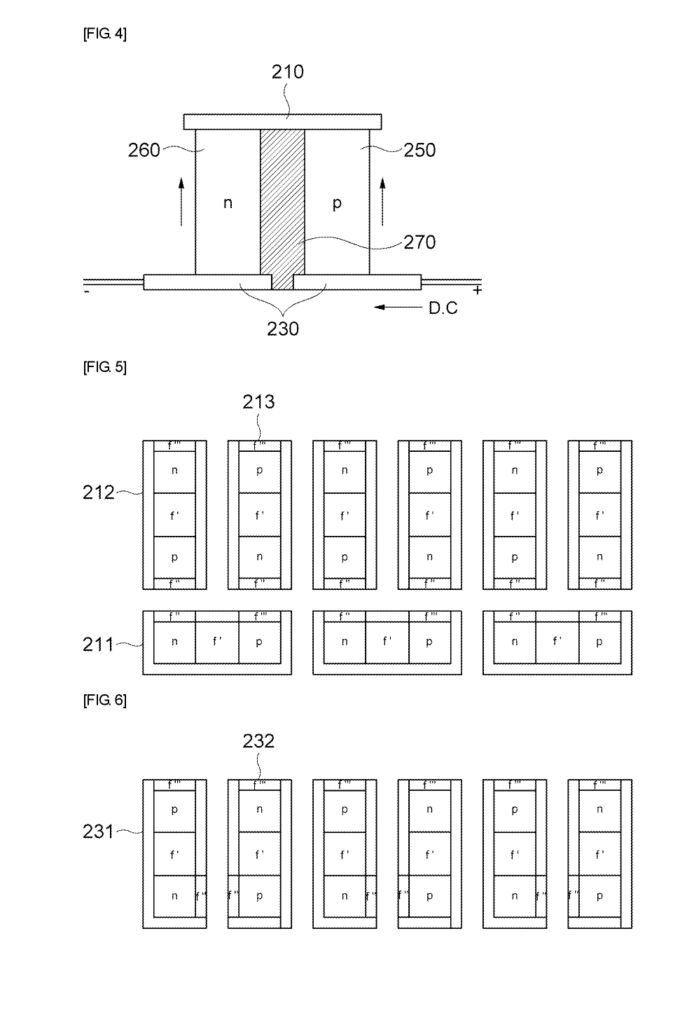

FIG. 5 is a diagram showing only a portion of the upper metal electrode 210 included in the thermoelectric module 200 according to the exemplary embodiment of the present invention and FIG. 6 is a diagram showing only a portion of the lower metal electrode 230 included in the thermoelectric module 200 according to the exemplary embodiment of the present invention. Describing in detail a connection structure between the ferrite element 270 disposed between the p-type semiconductor device 250 and the n-type semiconductor device 260 and the upper and lower metal electrodes 210 and 230 with reference to FIGS. 5 and 6, the top end and the bottom end of the ferrite element 270 may be bonded to the upper metal electrode 210 and the lower metal electrode 230, respectively.

Therefore, the upper metal electrode 210 and the lower metal electrode 230 may each be formed to have an n area in which the n-type semiconductor device 260 is bonded thereto, a p area in which the p-type semiconductor device 250 is bonded thereto, and an f area in which the ferrite element 270 is bonded thereto. In particular, the f area may be formed to include three areas f′, f″, and f″′.

Describing the upper metal electrodes 210 (hereinafter, referred to as metal electrodes 211, 212, and 213) represented by reference numerals 211, 212, and 213 among the plurality of upper metal electrodes 210 shown in FIG. 5 and the lower metal electrodes 230 (hereinafter, referred to as metal electrodes 231 and 232) represented by reference numerals 231 and 232 among the plurality of lower metal electrodes 230 shown in FIG. 6 as an example, the bottom ends of the ferrite elements bonded to the f′ area in metal electrode 211 are each bonded to the f″ area of metal electrode 231 and the f″ area of metal electrode 232, the top ends of the ferrite elements bonded to the f′ area in metal electrode 231 are each bonded to the f″ area of metal electrode 211 and the f″ area of metal electrode 212, the top ends of the ferrite elements bonded to the f′ area in metal electrode 232 are each bonded to the f′″ area of metal electrode 211 and the f″ area of metal electrode 213, and the ferrite elements 270 disposed between the other remaining p-type semiconductor devices 250 and n-type semiconductor devices 260 may also be connected to the upper and lower metal electrodes 210 and 230 as the above-mentioned structure.

That is, the f′ area in the f area is an area (or, an area in which the bottom end of the ferrite element 270 disposed between the n-type semiconductor device 260 and the p-type semiconductor device 250 of the lower metal electrode 230 is bonded to the lower metal electrode 230) in which the top end of the ferrite element 270 disposed between the n-type semiconductor device 260 and the p-type semiconductor device 250 of the upper metal electrode 210 is bonded to the upper metal electrode 210 and the f″ or f″′ area is an area (or, an area in which the top end of the ferrite element 270 disposed between the n-type semiconductor device 260 and the p-type semiconductor device 250 of the lower metal electrode 230 is bonded to the upper metal electrode 230) in which the bottom end of the ferrite element 270 disposed between the n-type semiconductor device 260 and the p-type semiconductor device 250 of the upper metal electrode 230 is bonded to the lower metal electrode 230.

In the ferrite element 270 showing the spin Seebeck effect, when the upper and lower metal electrodes 210 and 230 applies DC voltage through the foregoing connection structure using a first metal electrode 233 of the plurality of lower metal electrodes 230 as a positive (+) side and a second metal electrode 234 as an negative (−) side, the spin direction of electrons within the ferrite element 270 is aligned by the spin Seebeck effect, such that the top surface of the ferrite element 270 absorbs heat from the surroundings and the bottom surface of the ferrite element 270 discharges heat, thereby moving heat.

In addition, when the DC voltage is applied through the above-mentioned connection structure using the first metal electrode 233 of the plurality of lower metal electrodes 230 as a positive (+) side and the second metal electrode 234 as an negative (−) side, holes within the p-type semiconductor device 250 moves to an negative pole and electrons within the n-type semiconductor device 260 moves to a positive pole. In this case, all the holes and electrons move to the lower metal electrode 230 while having heat from the upper metal electrode 210 to cool the upper substrate 220 part, thereby absorbing heat from the surroundings and discharging heat from the lower substrate 240 part, thereby moving heat.

As described above, according to the thermoelectric module 200 of the exemplary embodiment of the present invention, since heat is moved by the n-type and p-type semiconductor devices 250 as well as heat moved by the ferrite element 270, the thermoelectric performance can be improved greater than the thermoelectric module configured only in the existing n-type and p-type and since the n-type semiconductor device 260 and the p-type semiconductor device 250 may be spaced apart from each by the ferrite element 270, the phenomenon in which the n-type semiconductor device 260 and the p-type semiconductor device 250 are short can be prevented, unlike the thermoelectric module 100 according to the related art. In addition, the exemplary embodiment of the present invention can maintain the operation state of the thermoelectric module by the ferrite element 270 even though the p-type semiconductor devices 250 or the n-type semiconductor devices 260 are defective, thereby improving the reliability of products.

Meanwhile, a cross-sectional area of the f′ area may be formed to be wider than that of an n area or a p area, respectively. When the cross-sectional area of the f′ area is formed to be wider than that of the n area or the p area, respectively, electrons within the ferrite element 270 showing the spin Seebeck effect are increased, thereby improving the thermoelectric performance.

In addition, in the thermoelectric module 200 according to the exemplary embodiment of the present invention, it is apparent to those skilled in the art that the form of providing the ferrite element 270 may be variously configured within the range in which the ferrite element 270 may be operated as the thermoelectric module by being bonded to the upper and lower metal electrodes 210 and 230.

As set forth above, the exemplary embodiment of the present invention can increase the thermoelectric performance by implementing the movement of heat by the ferrite elements in addition to the movement of heat by the p-type semiconductor devices and the n-type semiconductor devices.

Further, the exemplary embodiment of the present invention includes the ferrite elements between the p-type semiconductor devices and the n-type semiconductor devices, thereby preventing a short between the p-type semiconductor devices and the n-type semiconductor devices and improving the durability of the thermoelectric module.

In addition, the exemplary embodiment of the present invention can maintain the operation state of the thermoelectric module by the ferrite elements even though the p-type semiconductor devices or the n-type semiconductor devices are defective, thereby improving the reliability of products.

While the present invention has been shown and described in connection with the exemplary embodiments, it will be apparent to those skilled in the art that modifications and variations can be made without departing from the spirit and scope of the invention as defined by the appended claims.

What is claimed is:

1. A thermoelectric module, comprising:
an upper substrate on which a plurality of upper metal electrodes are arranged;
a lower substrate on which a plurality of lower metal electrodes are arranged;
p-type semiconductor devices and n-type semiconductor devices that are disposed between the upper substrate and the lower substrate and are electrically bonded alternately to each other by the plurality of upper metal electrodes and the plurality of lower metal electrodes; and
ferrite elements that are disposed between the p-type semiconductor devices and the n-type semiconductor devices, top ends and bottom ends of the ferrite elements being bonded to the upper metal electrodes and the lower metal electrodes.

2. The thermoelectric module according to claim 1, wherein the ferrite element includes at least any one of spinel ferrite, garnet ferrite, and metal oxide.

3. The thermoelectric module according to claim 1, wherein one side of the ferrite element is bonded to a p-type (or n-type) semiconductor device and/or the other side of the ferrite element is bonded to an n-type (or p-type) semiconductor device.

4. The thermoelectric module according to claim 1, wherein the upper metal electrode and the lower metal electrode are formed to have an n area in which the n-type semiconductor device is bonded thereto, a p area in which the p-type semiconductor device is bonded thereto, and f′, f″, and f′″ areas in which the ferrite element is bonded thereto.

5. The thermoelectric module according to claim 4, wherein a cross-sectional area of the f′ area is formed to be wider than that of an n area or a p area, respectively.
